(19) United States
(12) Patent Application Publication
(10) Pub. No.: US 2018/0313878 A1
(43) Pub. Date: Nov. 1, 2018

(54) NOVEL METHOD FOR CHECKING THAT A POWER AMPLIFIER IS OPERATING CORRECTLY

(71) Applicant: Claude CARPENTIER, Malsons Laffitte (FR)

(72) Inventor: Claude CARPENTIER, Malsons Laffitte (FR)

(21) Appl. No.: 15/768,558

(22) PCT Filed: Oct. 17, 2016
(86) PCT No.: PCT/FR2016/000168

§ 371 Date: Apr. 16, 2018

(30) Foreign Application Priority Data
Oct. 20, 2015 (FR) 15/02206

(51) Int. Cl. G01R 23/20; G01R 31/40

(52) U.S. Cl. CPC G01R 23/20; G01R 31/40

(57) ABSTRACT

The invention relates to a method for the real-time evaluation of the distortion of a power amplifier. The method is based on a continuous measurement of the gain of the amplifier and on a calculation of the relationship between successive maximum and minimum gains.

The present invention is a new method for controlling the proper operation of a power amplifier.

A power amplifier is a device designed to deliver at its output, a signal of identical shape to the input signal but whose voltage and/or intensity is increased so as to ensure the proper operation of the device that he is in charge of driving.

In particular, an audio amplifier at the input of which a signal of a few millivolts under high impedance is introduced must be capable of delivering at its output several amperes of intensity at voltages of several volts in order to ensure the proper operation of the speakers he has to drive.

Each power amplifier is designed to operate within certain limits. These limits are its characteristics that the manufacturer provides, which allows the user to choose a device whose characteristics are compatible with the intended use.

The main features of a power amplifier are:
its maximum output voltage V_{MO}
its maximum voltage gain G_{M}
maximum powers delivered for current load impedances

When the input voltage V_{IN} is too high, the requested output voltage is greater than V_{MO} and the amplifier is clipping.

Some devices and especially professional devices are equipped with a display of the output voltage which is usually a LED ramp. The first LEDs to light up are green and indicate that everything is fine then orange LEDs indicate that the output voltage approaches to the maximum voltage and when the output voltage reaches or exceeds the maximum voltage, at least one red led lights to alert the user that the amplifier is clipping.

Clipping control is, to our knowledge, the only device available to users for controlling the proper functioning of power amplifiers.

However, clipping is not the only cause of distortion. In particular, when the load impedance is too low, the power supply does not provide the requested power, the output voltage is lower than it should be and therefore the amplifier operates poorly.

The present invention is a new method of controlling the proper operation of a power amplifier capable of detecting any form of distortion and which can provide in real time to the user an indication of the distortion rate of the amplifier.

The classical method for measuring the distortion of an amplifier is to introduce at its input a sinusoidal signal and to examine the output signal through a specialized measuring device capable of providing in real time the total distortion rate THD and all its harmonic components H₂, H₃ . . . .

$$THD = \frac{\sqrt{{H}_{2}^{2} + {H}_{3}^{2} + …}}{F} \qquad ( 1 )$$

But, to our knowledge, there is no device capable of providing in real time a fairly accurate indication of the distortion rate of an amplifier listening to any piece of music.

The present invention is a method for realizing a device providing in real time an indication of the distortion rate of a power amplifier on any piece of music.

This process is based on controlling the instantaneous gain of the amplifier. Indeed, for the output signal to be of the same shape as the input signal, it is mandatory that the gain be constant. Any variation of this gain means a modification of the output signal with respect to the input signal and thus of the distortion.

By measuring the instantaneous gain of an amplifier and comparing successive measurements, it is therefore possible to detect the gain variations and therefore the distortions.

We will examine the ratios between distortion and gain variation for harmonics 2 and 3 for an amplifier whose voltage gain is 1 to simplify the presentation.

FIG. 1 shows in fine lines a period of a sinusoidal signal and two periods of its harmonic 2 at the rate of 10%. The curve in strong line is the distorted signal, addition of the pure signal and its harmonic.

The curve of FIG. 2 is the ratio of the voltages of the distorted signal to the original signal. Here, the gain varies from 0.8 to 1.2 in a ratio of 1.5.

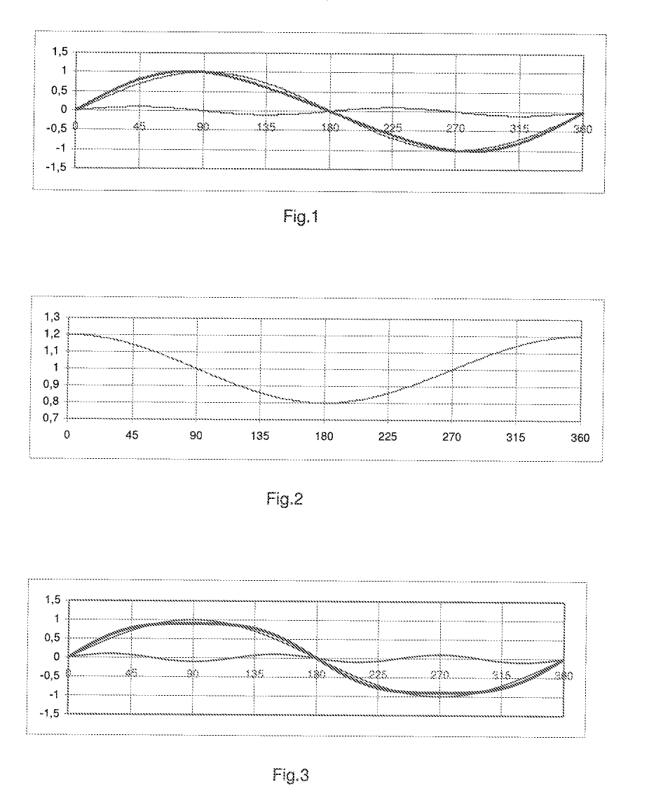

FIG. 3 shows in fine lines a period of the same sinusoidal signal and three periods of its harmonic 3 at the rate of 10%. The curve in strong line is the distorted signal, addition of the pure signal and its harmonic.

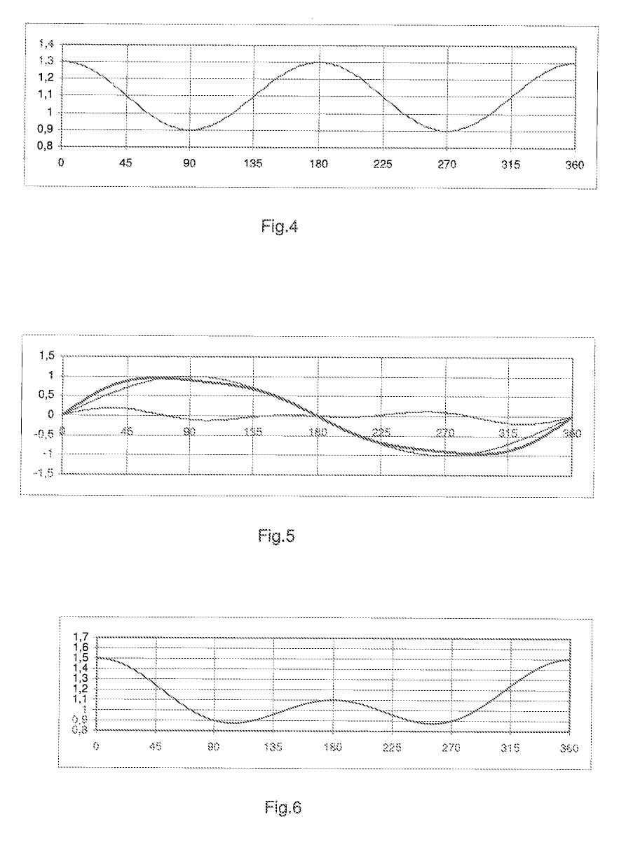

The curve of FIG. 4 is the ratio of the voltages of the distorted signal to the original signal. Here, the gain varies from 0.9 to 1.3 in a ratio of 1.46.

FIG. 5 shows in fine lines a period of the same sinusoidal signal and the addition of its harmonics 2 and 3 at the rate of 10%. The curve in strong line is the distorted signal, addition of the pure signal and its harmonics.

The curve of FIG. 6 is the ratio of the voltages of the distorted signal and the original signal. Here, the gain varies from 0.87 to 1.5 in a ratio of 1.72.

The harmonic distortions thus cause percentages of instant gain variations 4 to 5 times greater than the percentage of distortion.

We will introduce the notion of gain distortion rate. If G_{SD} is the gain without distortion and G_{R} the real gain at a given moment, the instantaneous gain distortion rate is:

$${TGD}_{I} = \frac{\vert {G}_{SD} - {G}_{R} \vert}{{G}_{SD}} \qquad ( 2 )$$

As shown in the curve of FIG. 2, for the distortion by harmonic 2 and also for all the distortions by even harmonics the average gain is 1 which makes it possible by calculating the average of the gains to find again G_{SD}.

But as the curve of FIG. 4 shows, for the distortion by harmonic 3 and for all odd-order distortions the average gain is not equal to 1, so the gain G_{SD} is unknown except for fixed gain amplifiers.

We must therefore find another method of evaluating the gain distortion.

By examining the curves of FIGS. 2, 4 and 6 we realize that the real gain G_{R} passes successively by maximums G_{M} and minimums Gₘ.

By storing the values of G_{M} and of Gₘ each time the slope of the gain curve is reversed we can deduce a sequential gain distortion rate TGD_{S} as the ratio of the difference of two G_{M} and Gₘ successive to the average gain during this sequence. We have:

$${TGD}_{S} = 2 \times \frac{{G}_{M} - {G}_{m}}{{G}_{M} + {G}_{m}} \\ \begin{matrix}For {H}_{2} & {TGD}_{S} = 2 \times \frac{1.2 - 0.8}{1.2 + 0.8} = 0.40 = 40 \% \\ For {H}_{3} & {TGD}_{S} = 2 \times \frac{1.3 - 0.9}{1.3 + 0.9} = 0.36 = 36 \% \\ For {H}_{2} and {H}_{3} & {TGD}_{S} = 2 \times \frac{1.5 - 0.9}{1.5 + 0.9} = 0.50 = 50 \%\end{matrix} \qquad ( 3 )$$

If we divide TGD_{S} by 4, we obtain a value close to the harmonic distortion, and thus an indication of a sufficient precision of the distortion rate THD of the amplifier.

The realization of a device for measuring the rate of gain distortion according to the present invention will not pose any difficulty to one skilled in the art of numerical calculation.

When a device will be equipped with several power amplifiers, it will be possible to measure the gain distortion for each of them and for reasons of economy, to communicate to the user only the highest distortion. The user interface can take many forms, the classic form of which will be to light green leds as the distortion will be much lower than the audible threshold, to turn on at least one orange led as soon as the distortion approaches the threshold of audibility and to light at least one red led as soon as one reaches and/or exceeds the audible distortion threshold.

In this way the user will permanently know if his power amplifier correctly reproduces the modulation it is responsible for amplifying or not.

1. A method for evaluating the distortion rate of a power amplifier, characterized in that the input voltage and the output voltage are continuously measured, and that the ratio between its output voltage and its input voltage is continuously calculated that when there is distortion this gain varies between maximums G_{M} and minimums Gₘ and that we use the ratio between consecutive G_{M} and Gₘ or a function of this ratio to evaluate the rate of distortion of the amplifier

2. Device for evaluating the distortion rate of a power amplifier comprising means for measuring the input voltage, means for measuring the output voltage, means for calculating the ratio of the output voltage to the input voltage, means for storing this report when it passes through maximums G_{M} and when it passes through a minimum Gₘ means for calculating the ratio or a function of this ratio between G_{M} and Gₘ consecutive and an interface providing to the user an indication of amplifier distortion based on the results of this calculation.

3. Power amplifier equipped with a device according to claim 2.

4. A sound reproducing apparatus comprising a plurality of power amplifiers equipped with a device according to claim 2 and characterized in that one communicates at least to the user an indication of the highest distortion.
